(19) United States
(12) Patent Application Publication
(10) Pub. No.: US 2026/0047048 A1
(43) Pub. Date: Feb. 12, 2026

(54) Cooling Module With Improved Flow Balancing, Jet-Height Control, and Wash-Out Mitigation

(71) Applicant: Jetcool Technologies Inc., Littleton, MA (US)

(72) Inventor: Robert BALLERSTEDT, Littleton, MA (US)

(73) Assignee: Jetcool Technologies Inc., Littleton, MA (US)

(21) Appl. No.: 19/297,606

(22) Filed: Aug. 12, 2025

Related U.S. Application Data
(60) Provisional application No. 63/682,142, filed on Aug. 12, 2024.

(51) Int. Cl. H05K 7/20

(52) U.S. Cl. CPC H05K 7/20272

(57) ABSTRACT

A modular liquid-cooling apparatus is disclosed for dissipating heat from electronic devices via high-velocity jet impingement. The apparatus comprises a thermally conductive, substantially flat base plate; a jet plate with an array of nozzles and optional fluid exit port holes; and a thin standoff interposed between the plates. The standoff precisely fixes jet height, partitions the impingement region into multiple discrete chambers using integrated effluent isolators, and contains exit slots of variable size and pitch. These effluent isolators are thin cross bars that prevent impinged fluid from traveling long distances across the impingement surface, instead forcing effluent to exit locally through the nearest slot, thereby substantially mitigating jet wash-out and preserving the performance of adjacent jets. A housing surrounds these elements, forming an inlet plenum, connecting spurs, and an exit channel coupled to inlet and outlet ports. Effluent coolant is routed through the standoff directly into the connecting spurs, minimizing lateral travel and equalizing flow across the module. The standoff may be inexpensively fabricated from sheet metal or polymer, enabling rapid, low-cost customization without machining complex features into the base plate. The configuration provides superior flow balancing, lower differential pressure, and improved thermal performance compared with conventional cold plates.

### FIELD OF THE INVENTION

The present invention pertains to thermal management of electronic devices. More particularly, it relates to a modular liquid-cooled impingement apparatus having a jet plate, a flow-routing standoff, and an internal housing architecture that collectively provide enhanced flow balancing, reduced differential pressure, and substantial mitigation of jet wash-out effects.

### BACKGROUND OF THE INVENTION

High-power electronic components—processors, ASICs, power amplifiers, and similar devices—generate heat fluxes that cannot be dissipated adequately with conventional air cooling. As a result, liquid-cooled jet-impingement cold plates have been developed to improve thermal resistance and enable higher performance. However, these conventional cooling modules are not without significant drawbacks.

A major limitation of prior art cooling modules is the reliance on complex structures and flow-routing features that are directly integrated into the base plate, typically through precision machining. These intricate channels and cavities are intended to manage coolant distribution and effluent removal, but their integration into the base plate introduces several disadvantages. The manufacturing process for such base plates is both time-consuming and expensive, often requiring multiple machining steps, specialized tooling, and high-quality copper or other conductive materials. This not only increases the overall cost of the cooling module but also results in long lead times, making it difficult to rapidly iterate or customize designs for specific electronic devices or applications.

Furthermore, the integration of flow-routing features into the base plate severely limits material and geometric flexibility. Because the base plate must serve both as the primary heat-transfer interface and as the structural foundation for fluid management, any changes to the flow path or jet array typically necessitate a complete redesign and remanufacture of the base plate itself. This lack of modularity hinders rapid prototyping and adaptation to new device requirements, and it restricts the use of alternative materials that might otherwise offer advantages in cost, weight, or manufacturability.

In addition to manufacturing challenges, prior designs often suffer from suboptimal fluid dynamics. The complex internal channels can create regions of flow maldistribution, where coolant is unevenly distributed across the impingement surface. This leads to temperature non-uniformity and localized hot spots, reducing the overall effectiveness of the cooling module. Moreover, the effluent fluid in these designs may be forced to travel significant lateral distances before exiting the module, increasing the likelihood of jet wash-out. In this phenomenon, the post-impingement fluid disrupts the performance of adjacent jets, degrading heat-transfer coefficients and further exacerbating thermal non-uniformity.

These limitations underscore the need for a new cooling module architecture that decouples flow-routing features from the base plate, enabling precise control of jet height, improved flow balancing, rapid effluent removal, and substantial mitigation of wash-out effects. Such an approach would also facilitate rapid, low-cost customization and manufacturing flexibility, overcoming the key disadvantages of prior art cooling modules.

### SUMMARY OF THE INVENTION

Embodiments of the present invention provide a modular cooling module for efficiently dissipating heat from electronic devices, such as processors or power amplifiers. The module comprises a housing, a jet plate, a standoff, and a thermally conductive base plate—preferably copper, copper alloy, or aluminum—with a substantially flat impingement surface to maximize thermal conductivity and minimize manufacturing complexity.

The jet plate, positioned above the base plate, features an array of precision nozzles and optional fluid exit port holes. These nozzles generate high-velocity jets of coolant that impinge directly onto the base plate, rapidly extracting heat. Optional fluid exit port holes allow a portion of post-impingement coolant to exit the impingement area swiftly and efficiently and flow into an exit channel, minimizing pressure drop, promoting balanced pressure distribution and reducing stagnation in the impingement area.

A standoff is interposed between the jet plate and the base plate. The thickness of the standoff sets the jet height—the distance from the nozzle exits to the impingement surface. The standoff also supports the jet plate under compression and defines discrete flow-routing boundaries within the impingement region. Integrated effluent isolators confine post-impingement coolant and direct it to the nearest exit slots, preventing lateral washout across the base plate and interference with adjacent jets.

The housing encloses all internal components and incorporates an inlet plenum for uniform coolant distribution, connecting spurs for rapid effluent removal, and an exit channel leading to an outlet port. Standard inlet and outlet ports allow integration with external cooling loops, including pumps, radiators, and reservoirs.

Exit slots of predetermined width and pitch in the standoff and housing enable immediate routing of effluent coolant to connecting spurs, minimizing travel distance and balancing flow. This design substantially reduces jet wash-out, lowers differential pressure, and equalizes heat-transfer performance across the device.

The standoff may be fabricated from sheet metal, plastic, thermoplastic, or thermoset resin using die-cutting, laser cutting, injection molding, water-jet cutting, or die casting. The flat base plate allows rapid, low-cost customization by exchanging the standoff or jet plate without re-machining the base plate, supporting flexible adaptation for diverse cooling applications.

### BRIEF DESCRIPTION OF THE DRAWINGS

FIG. 1 is a perspective view of the cooling module as seen from above, illustrating the external housing, inlet and outlet ports, and the general configuration of the assembled module.

FIG. 2 is a perspective view of the cooling module as seen from below, showing the bottom surface of the base plate and the flat area intended for thermal contact with a heat-generating electronic component.

FIGS. 3A, 3B, and 3C are, respectively, a top plan view, a top perspective view, and a bottom perspective view of the base plate removed from the cooling module, highlighting the flat impingement surface and mounting features.

FIG. 4 is an exploded perspective view of the cooling module, illustrating the sequential arrangement of the base plate, standoff, jet plate, and housing.

FIGS. 5A and 5B are, respectively, a top plan view and a perspective view of the standoff, showing the arrangement of effluent isolators and exit slots.

FIG. 6 is a top plan view of the jet plate, depicting the array of nozzles and optional fluid exit port holes.

FIGS. 7A, 7B, and 7C are, respectively, a perspective view from above, a plan view from above, and a plan view from below of the connection apron of the housing, illustrating the structural interface and integration of ports and connecting spurs.

FIGS. 8A, 8B, and 8C are, respectively, a plan view of the cooling module from above, a cross-sectional view along line B-B, and a cross-sectional view along line C-C, showing the internal arrangement and fluid pathways.

FIGS. 9A and 9B are enlarged cross-sectional views taken along line C-C of FIG. 8A. further illustrating the coolant flow path through the module and the function of the effluent isolators and exit slots.

FIG. 10A is an orthogonal side view of the fully assembled cooling module.

FIG. 10B is a cross-sectional view taken along line E-E of FIG. 10A, showing the interface between the jet plate and standoff, and the partitioning of the impingement region into discrete flow chambers by the effluent isolators.

FIG. 11 is a schematic diagram of an exemplary external fluid-delivery system connected to the cooling module, illustrating integration with a fluid manifold and coolant distribution unit.

### DETAILED DESCRIPTION OF THE INVENTION

The general construction of the improved cooling module is best understood with reference to the figures described below, which illustrate the arrangement and function of the primary components and their interaction during operation.

The construction and operation of the cooling module are illustrated in detail in the accompanying figures and subsequent descriptions. At a high level, however, the cooling module comprises several key components arranged to establish a precise and efficient fluid flow path, as outlined immediately below:

When coolant is pumped through into the cooling module via an inlet port, it passes into an inlet plenum inside the cooling module between the ceiling of the housing and a jet plate, where static pressure is equalized. The coolant is then forced through an array of nozzles in the jet plate, forming discrete, high-velocity impingement jets that strike the impingement surface of the base plate at precisely controlled locations. This impingement action on the base plate extracts heat from the electronic device in thermal communication with the base plate with high efficiency, as the kinetic energy of the jets is rapidly converted into thermal energy transfer at the solid-liquid interface.

Immediately after impact, the effluent coolant is constrained by effluent isolators integrated into a standoff. These effluent isolators partition the impingement surface of the base plate into multiple discrete chambers, each corresponding to a subset of the nozzles in the jet plate. The effluent is thus forced to exit through the nearest exit slots in the standoff, which are strategically positioned along the perimeter of each chamber. This design minimizes lateral travel of the effluent across the impingement surface, thereby preventing the effluent from interfering with neighboring jets—a phenomenon known as jet wash-out. By containing the effluent within its designated chamber and routing it efficiently to the exit slots, the system maintains uniform heat-transfer performance and reduces pressure drop across the cooling module. The effluent from all chambers subsequently converges within an exit channel defined by the geometry of the housing, and is discharged from the cooling module via an outlet port, completing the fluid circuit.

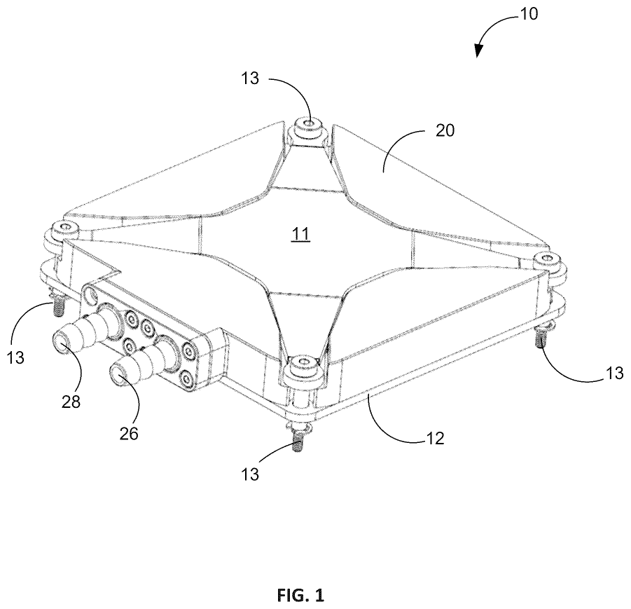

Turning now to the figures, FIG. 1 shows an external perspective view of a cooling module 10 according to one embodiment of the present invention, as seen from above. As shown in this view, the cooling module 10 includes a housing 20 that is secured to the base plate 12 using four compression screws 13 threaded through a tensioner device 11 and corresponding screw-receiving holes in the base plate 12. The housing 20 is equipped with an inlet port 26 and an outlet port 28, which are designed for fluid connection to an external fluid distribution system 30 (not shown in FIG. 1). The inlet port 26 and outlet port 28 are typically formed as one-quarter (¼) inch and/or one-half (½) inch hose barb fittings, or any other type of fitting required by the particular environment or application, facilitating easy integration with standard cooling loops and external fluid-delivery systems.

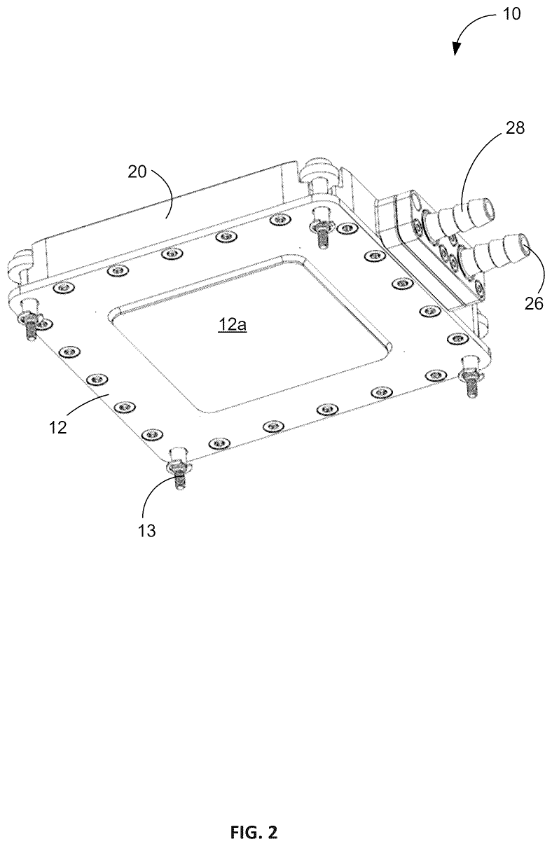

FIG. 2 presents an external perspective view of cooling module 10, as observed from below. This vantage point reveals the bottom surface of the base plate 12, which features a raised substantially flat area 12a specifically engineered for direct thermal contact with a heat-generating electronic component, such as a processor, ASIC, or power amplifier (not shown in the figure). The flatness of area 12a is intended to maximize the efficiency of heat transfer from the heat-generating electronic device to the cooling module while minimizing manufacturing complexity and cost.

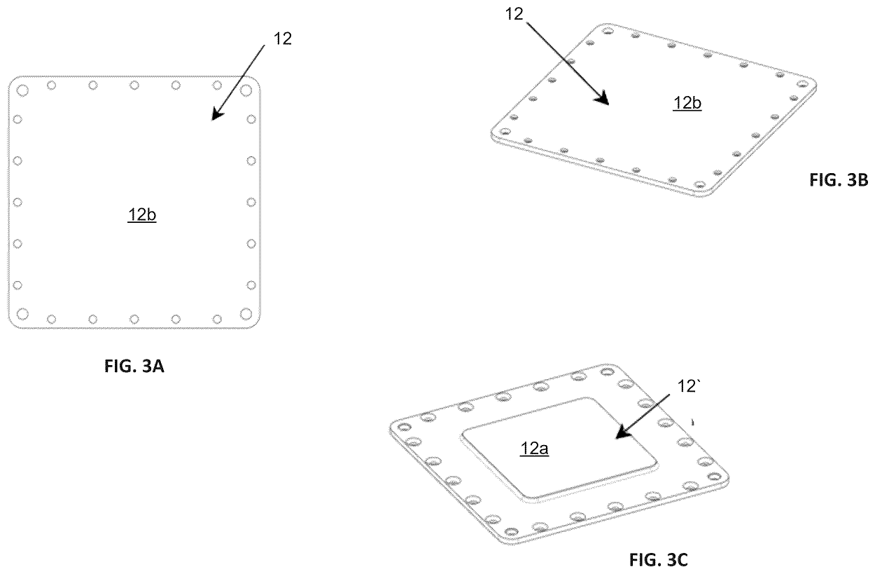

FIGS. 3A, 3B and 3C show, respectively, a top plan view, a top perspective view and a bottom perspective view of the base plate 12, removed from the rest of the cooling module 10 to better show both the top and the bottom surfaces of base plate 12. The top of base plate 12 has a flat impingement surface 12b directly opposite from the flat area 12a that comes into contact with the heat-generating electronic component. The base plate 12 also has a series of holes 12c configured to permit the standoff 14 (not shown in in FIGS. 3A, 3B and 3C) to be secured to the base plate 12 using screws (not shown) or another type of suitable fastener.

The base plate 12 is generally rectangular and is typically made from a highly conductive material such as copper, copper alloy, or aluminum to ensure efficient thermal performance. Its flat impingement surface 12b provides a uniform interface for the high-velocity coolant jets generated within the cooling module 10, promoting consistent cooling across the entire impingement surface 12b. Unlike conventional cold plates that require complex machined channels or cavities for fluid management, the base plate 12 is characterized by a substantially flat impingement surface 12a, a feature that minimizes manufacturing cost and complexity while maximizing thermal conductivity and uniformity of heat transfer.

FIGS. 2 and 3A-3C illustrate the practical advantages of the improved cooling module 10: a flat, thermally efficient base plate 12 for direct contact with heat sources, a modular assembly that simplifies manufacturing and customization, and an external configuration that supports rapid integration into various electronic systems. This approach enables effective heat dissipation, reduced manufacturing costs, and enhanced adaptability for a wide range of cooling applications.

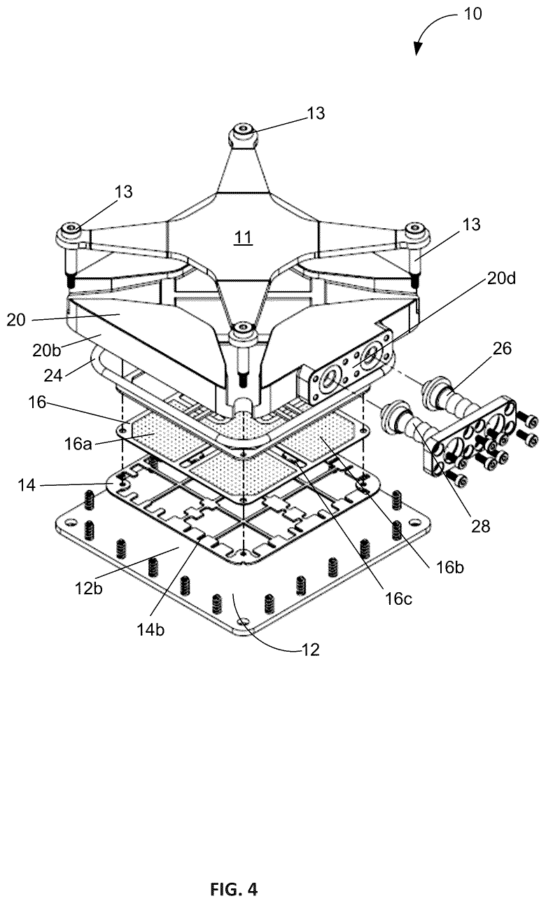

FIG. 4 provides an exploded perspective view of the improved cooling module 10, illustrating the sequential arrangement and functional relationships of its primary components: the base plate 12, standoff 14, jet plate 16, and housing 20. This diagram visually separates each element, allowing for a detailed understanding of how the cooling module 10 is assembled and how each part contributes to the overall performance. At the bottom of the assembly is the base plate 12. Positioned directly above the base plate 12 is the standoff 14. Above the standoff 14 sits the jet plate 16. The jet plate 16 contains an multiplicity of nozzles 16a arranged in an array 16b, which is precisely aligned with the impingement surface 12b of the base plate 12 below. The standoff 14 serves several functions: it precisely sets the jet height (the distance between the nozzles 16a in the jet plate 16 and the base plate 12), provides mechanical support under compression loads, and, most importantly, manages fluid flow on top of the impingement surface 12b of the base plate 12. The exploded view in FIG. 4 highlights the modularity of the improved cooling module 10. By separating the flow-routing and jet-forming features of cooling module 10 into the standoff 14 and jet plate 16, the improved design enables more efficient heat transfer, rapid customization and low-cost manufacturing.

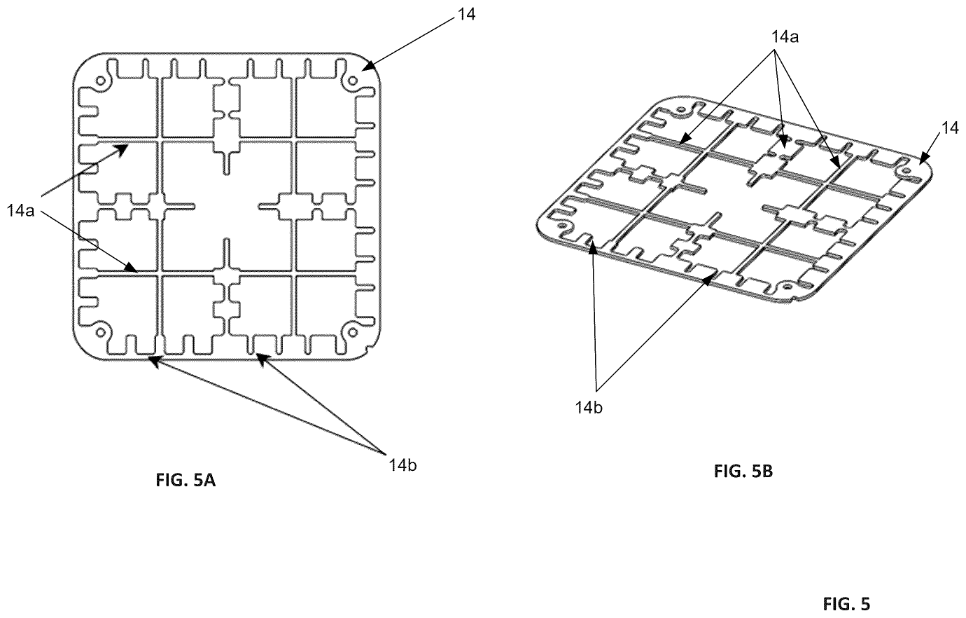

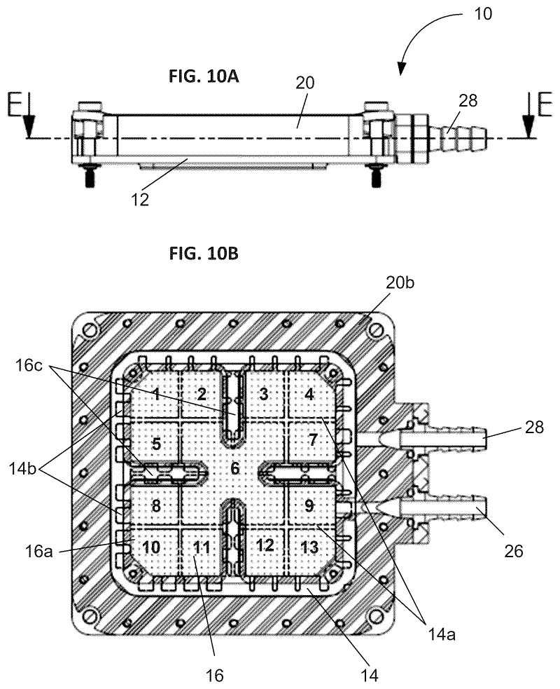

FIGS. 5A and 5B illustrate, respectively, a top plan view and a perspective view of the standoff 14, highlighting the arrangement and function of two of its key features—effluent isolators 14a and exit slots 14b. As shown, the standoff 14 is substantially rectangular, with length and width dimensions closely matching those of both the jet plate 16 and the top surface of the base plate 12, ensuring a precise fit and uniform assembly. The standoff 14 comprises a thin, precisely dimensioned component whose thickness—typically ranging from 0.2 mm to 1.5 mm—defines the jet height, or the distance from the nozzle exits to the impingement surface 12b. But the standoff 14 is not merely a vertical spacer; it is also a flow-routing element. Specifically, the standoff 14 is engineered to partition the impingement region 12b of the base plate 12 into multiple discrete flow chambers, each defined by the strategic placement of the effluent isolators 14a. These effluent isolators 14a, comprising, for example, thin strips and crossbars, extend upward from the primary surface of the standoff 14 toward the bottom of the jet plate 16, creating fluid boundaries (e.g., walls or pillars) between the standoff 14 and the jet plate 16 that confine the post-impingement effluent within the flow chamber where the effluent impinged on the impingement surface 12b. The partitioning and locations of the flow chambers are best illustrated in FIG. 10b, and will be described in more detail in connection with the description of FIG. 10b below.

Distributed along the perimeter of the standoff 14 are exit slots 14b, which preferably vary in size and spacing (pitch) to enable balanced coolant flow and effective mitigation of wash-out effects. The careful arrangement of the sizes and locations of these exit slots 14b ensures that effluent from each jet is routed efficiently to the nearest exit slot 14b, minimizing the distance the fluid must travel laterally across the impingement surface 12b before being routed out of the cooling module 10. This design prevents the effluent from interfering with the performance of adjacent jets, thereby preserving uniform heat-transfer performance and balanced pressure distribution across the entire cooling module 10. The number, size, and configuration of the discrete flow chambers can be tailored to the specific cooling requirements of a given application, allowing for precise tuning of flow balancing and wash-out mitigation. Additionally, this chambered configuration supports rapid customization and optimization of the cooling module 10 for different electronic devices simply by modifying the geometries of the standoff 14, the effluent isolators 14a, the exit slots 14b, or all of the above.

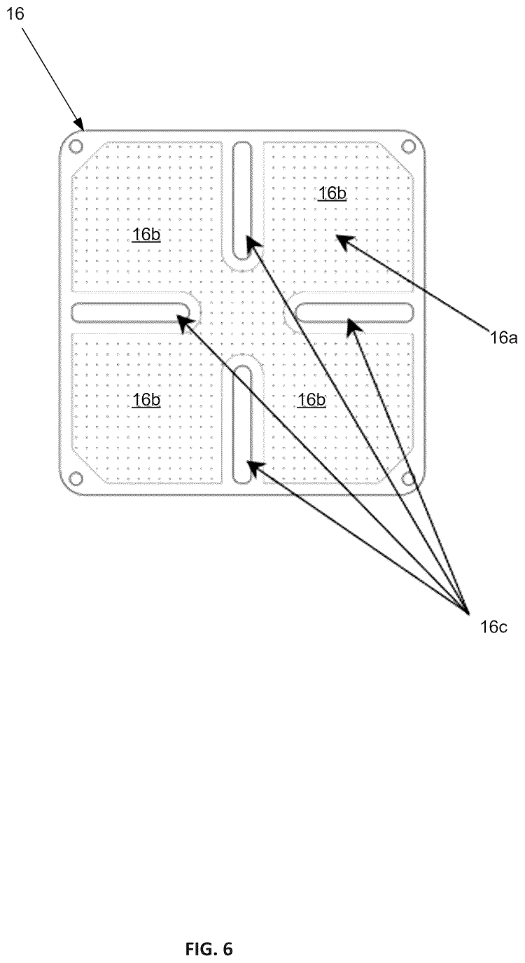

FIG. 6 provides a top plan view of the jet plate 16, which is a key component in the cooling module's thermal management strategy. The jet plate 16 features a multiplicity of precision-formed nozzles 16a, which are arranged into one or more regular or application-specific nozzle arrays 16b. These nozzles 16a are engineered to generate high-velocity jets of coolant that impinge directly onto the base plate's impingement surface 12b. The geometry of each nozzle—its diameter, shape (circular, elliptical, conical, chamfered or polygonal), and spacing—can be tailored to optimize jet velocity, coverage and cooling performance for the target electronic device. The nozzles 16a in the nozzle array 16b are typically formed using advanced manufacturing techniques such as laser drilling, chemical etching, or micro-machining, which allow for tight tolerances and consistent jet characteristics across the entire array.

In addition to the nozzles 16a in the nozzle array 16b, the jet plate 16 includes fluid exit ports 16c (or pass-through holes). These fluid exit port holes 16c are strategically positioned to interface with connecting spurs 20a defined by the housing 20 to facilitate the rapid removal of effluent coolant from the central regions of the impingement area, further reducing the risk of stagnation and promoting balanced pressure distribution. The inclusion of these fluid exit port holes 16c can be especially beneficial in applications where uniform flow and pressure are critical.

The overall thickness of the jet plate 16 may be carefully controlled to maintain structural integrity while minimizing flow resistance. Its flatness and rigidity ensure that the nozzle array 16b remains precisely aligned with the impingement surface 12b of the base plate 12, and that the jet height—set by the thickness of the standoff 14—remains consistent across the entire cooling module 10. This precise alignment helps in achieving uniform jet impingement, maximizing heat transfer, and ensuring reliable operation under varying thermal loads.

The jet plate 16 is typically fabricated from a thin, rigid material such as stainless steel, copper, or a high-performance polymer, selected for its durability, manufacturability, and compatibility with the coolant fluid. The jet plate 16 is generally rectangular to match the length and width dimensions of the standoff 14 and base plate 12, ensuring a tight, uniform assembly.

The combination of the standoff's chambered design and the jet plate's nozzle geometry enables the cooling module to deliver highly controlled, efficient, and customizable thermal management for high-power electronic devices. The modular architecture also allows for rapid adaptation to different cooling requirements by simply modifying the standoff 14 or jet plate 16 without requiring complex machining of the base plate 12 or housing 20.

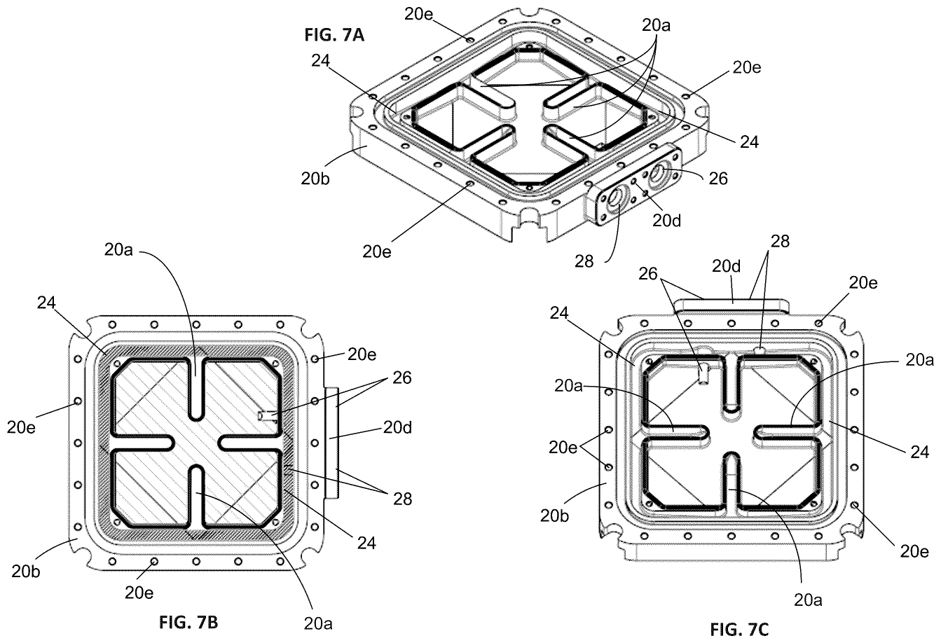

FIGS. 7A, 7B and 7C show, respectively, a perspective view from above, a plan view from above and a plan view from below of the connection apron 20b of the housing 20 in certain embodiments of the present invention. The connection apron 20b is a continuous collar or band that extends around the perimeter of the housing's lower edge, and serves as a robust structural interface between the housing 20 and the base plate 12, providing both mechanical support and a platform for integrating key functional elements of the cooling module 10, such as the input port 26, the output port 28 and the connecting spurs 20a of the housing 20.

The shape of the connection apron 20b is generally rectangular or conformal to the overall footprint of the housing 20, with a substantially uniform circumference that matches or projects outward from the lower rim of the housing 20. This design creates a stable flange-like surface that not only reinforces the housing 20 but also accommodates the precise alignment and secure attachment of the base plate 12 to the housing 20. In particular, the connection apron 20b is equipped with a series of evenly spaced screw holes 20e configured to accept screws (not shown) that are used to securely fasten the base plate 12 to the housing 20, ensuring a tight, leak-free seal and maintaining the structural integrity of the assembled cooling module 10. Other types of fasteners, such as adhesive, also may be used to attach the base plate 12 to the bottom of the housing 20.

The connection apron 20b also acts as the origin for the connecting spurs 20a. These connecting spurs 20a are internal extensions or ribs that project inward from the interior wall of the connection apron 20b toward the center of the cooling module 10. The connecting spurs 20a are strategically arranged to cooperate with the ceiling of the housing 20 to define and partition an inlet plenum 22—a chamber located between the ceiling of the housing 20 and the surface of the nozzle array 16b of the jet plate 16. The inlet plenum 22 is in direct fluid communication with the inlet port 26, allowing coolant entering through the inlet port 26 to be evenly distributed across the upper surface of the jet plate 16 before passing through the nozzle array 16b of the jet plate 16, thereby promoting even jet impingement and optimal thermal performance. Additionally, the connection apron's robust construction provides additional support for the connection spurs 20b, preventing deformation or misalignment under operational pressures and compression forces caused during assembly of the cooling module 10.

Integrated into (or connected to) the connection apron 20b is a platform 20d configured to support the inlet port 26 and the outlet port 28. These ports are typically formed as threaded or otherwise standardized fittings, allowing for straightforward connection to external fluid delivery systems. The inlet port 26 is configured to extend through the wall of the connection apron 20b, providing a direct and unobstructed path into the inlet plenum 22 defined by the connecting spurs 20a and the ceiling of the housing 20. The outlet port 28 passes through the wall of the connection apron 20b to make a fluid connection with the exit channel 24 of the housing 20, thereby providing an unobstructed flow path out of the cooling module 10 for returning post-impingement coolant back to the external fluid delivery system.

The exit channel 24 collects effluent that flows into the connecting spurs 20a and transports it to the outlet port 28 for discharge. In addition, the exit channel 24 is designed to receive and convey effluent that enters the exit channel 24 directly through the exit slots 14b of the standoff 14. As a result, some fluid enters the exit channel 24 from the connecting spurs 20a, while other fluid enters from the exit slots 14b in the standoff 14, ensuring efficient removal of effluent from multiple components within the cooling module.

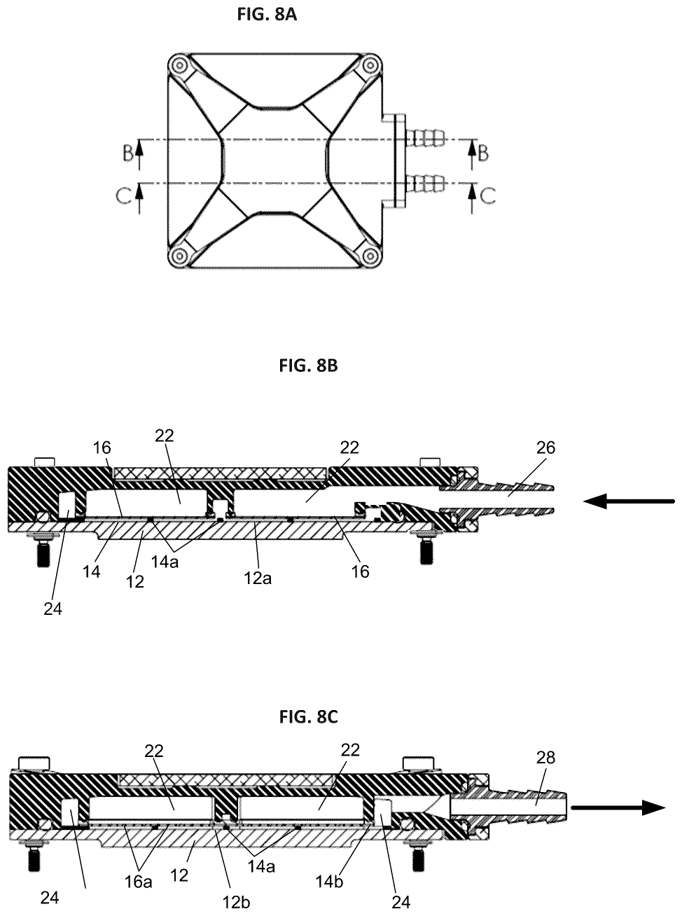

FIGS. 8A, 8B, and 8C provide, respectively, a plan view of the cooling module as viewed from above, a cross-sectional view of the fully assembled cooling module 10 cut along line B-B of FIG. 8A, and a cross-sectional view of the cooling module 10 cut along line C-C of FIG. 8A. Together, these three figures further illustrate the relative positions of the internal elements of the cooling module 10, as well as the internal fluid pathways within the cooling module 10.

As depicted in FIGS. 8B and 8C, coolant enters the cooling module 10 through the inlet port 26 and flows into the inlet plenum 22, where it is distributed across the surface of the jet plate 16. The jet plate 16 accelerates the coolant through the nozzles 16a of the nozzle array 16b, producing high-velocity jets that impinge on the impingement surface 12a of the base plate 12. After impingement, the effluent coolant is immediately directed by the effluent isolators 14a of the standoff 14 to the nearest exit slots 14b, and is then collected in the exit channel 24 before exiting the module via the outlet port 28.

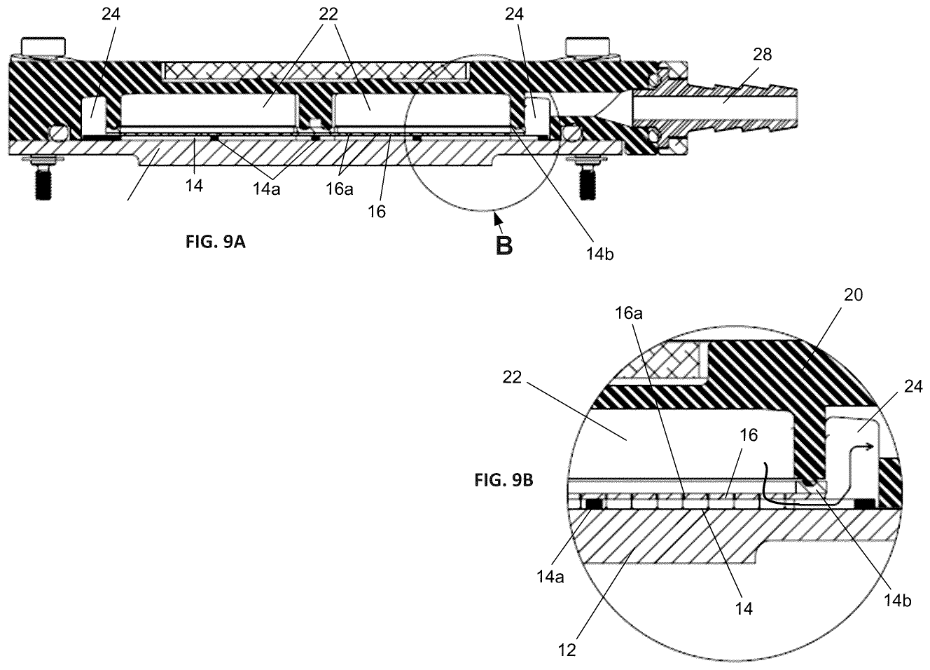

FIGS. 9A and 9B provide enlarged cross-sectional views of the cooling module 10, where the section cut is taken along line C-C of FIG. 8A. These views are provided to more clearly illustrate the coolant flow path through the cooling module 10. In these views, coolant is shown leaving the inlet plenum 22 to pass through the jet nozzles 16a, impinging on the base plate's impingement surface 12b, and then passing through the exit slots 14b in the standoff 14. From there, the coolant enters the exit channel 24, which is defined by the housing 20, and is ultimately discharged from the cooling module 10 through the outlet port 28.

The effluent isolators 14a are depicted as thin crossbars or strips of material integrated into the standoff 14, extending upward toward the jet plate 16. These isolators 14a partition the impingement surface 12b into multiple discrete flow chambers beneath the jet plate 16. Their primary function is to prevent the impinged coolant from traveling significant lateral distances across the impingement surface 12b toward the exit slots 14b, which would otherwise be the path of least resistance. Without these isolators 14a, effluent fluid could flow across the impingement region and disrupt the performance of adjacent jets.

By dividing the impingement region into isolated flow paths, the arrangement of effluent isolators 14a ensures that effluent is directed to the nearest exit slot 14b in the standoff 14. This design minimizes lateral flow post-impingement, reduces wash-out effects, and helps maintain balanced pressure distribution throughout the impingement surface 12b.

FIG. 10A provides an orthogonal side view of a fully assembled cooling module 10, while FIG. 10B presents a cross-sectional view taken along line E-E of FIG. 10A. In FIG. 10B, the interface between the jet plate 16 and the standoff 14 is shown, highlighting the distribution and arrangement of the effluent isolators 14a beneath the jet plate 16. These isolators create a series of discrete flow chambers between the jet plate 16 and the impingement surface 12b of the base plate 12 (shown in FIG. 10A, not shown in FIG. 10B). In this example, thirteen (13) separate flow chambers (labeled 1-13 in FIG. 10B) are formed by the effluent isolators 14a. This configuration forces the effluent coolant to flow directly to the nearest exit slots 14b in the standoff 14, rather than allowing it to travel laterally across the impingement surface 12b, which could disrupt the performance of adjacent jets. Fluid exit port holes 16c permit a portion of coolant to more quickly exit the impingement zone on the base plate 12 after impingement, which helps to improve pressure distribution in the cooling module. The presence and magnitude of the fluid exit port holes 16 may be tuned to allow all post-impingement fluid to exit swiftly and efficiently, so that all fluid has equal potential to exit the impingement area and enter the exit channel. This helps minimize pressure drops and balancing the flow through the cooling module 10.

Although the effluent isolators 14a are depicted in the figures as thin strips arranged at right angles to each other, forming a grid pattern, other arrangements are also possible depending on the desired flow characteristics, the locations of the exit slots 14b and the exit channel 24 defined by the housing 20. For example, the effluent isolators could be organized in concentric circles to suit a circular jet array, in a radial spoke pattern extending outward from a central point, or in a honeycomb or hexagonal grid to optimize chamber shape and flow distribution. The choice of pattern can be tailored to the specific cooling requirements, the geometry of the jet array, the layout of heat-generating elements beneath the base plate 12, or the layout of the exit slots in the standoff, allowing for flexible adaptation to various electronic device configurations and performance goals. The effluent isolators 14a do not even have to be thin strips. The effluent isolators may also be formed as walls, posts, or other suitable structures configured to direct effluent to the nearest exit slots.

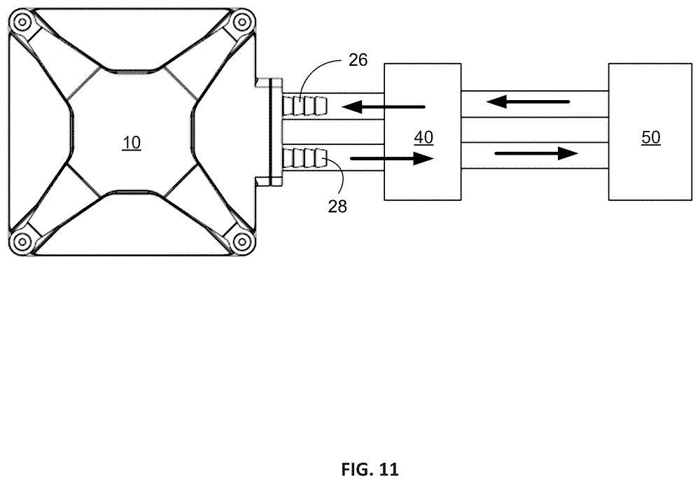

FIG. 11 is a schematic diagram illustrating an exemplary external fluid-delivery system connected to the inlet port 26 and outlet port 28 of the cooling module 10. In this configuration, the fluid delivery system comprises two primary components: a fluid manifold 40 and a coolant distribution unit 50. The fluid manifold 40 serves as a central hub for distributing coolant to one or more cooling modules, while the coolant distribution unit 50 typically includes a pump, reservoir, and associated control hardware necessary for circulating coolant throughout the system.

The diagram demonstrates how the cooling module 10 is integrated into a standard closed-loop liquid cooling circuit. Coolant is drawn from the reservoir in the coolant distribution unit 50 by the pump, which provides the necessary pressure to drive fluid through the manifold 40 and into the inlet port 26 of the cooling module 10. Upon entering the cooling module 10, the coolant passes through the internal flow path—first entering the inlet plenum 22, then being accelerated through the jet plate nozzles 16a, impinging on the impingement surface 12b of the base plate 12, and finally being routed through the exit slots 14b of the standoff 14, the exit channel 24 and the outlet port 28.

After absorbing heat from the electronic device (not shown in FIG. 11), the warmed coolant exits the cooling module 10 through the outlet port 28. It is then returned to the coolant distribution unit 50 via the fluid manifold 40, where it typically passes through a heat exchanger or radiator to dissipate the absorbed heat before re-entering the reservoir and repeating the cycle. The use of a fluid manifold 40 allows for scalable deployment, enabling multiple cooling modules to be connected in parallel or series, depending on the thermal management requirements of the system.

The design of the cooling module of the present invention offers significant material and manufacturing flexibility. Because the flow-routing features, including the effluent isolators and exit slots, reside primarily in the standoff and housing, the base plate can remain a simple milled or rolled planar element, free of complex machined channels or features. The standoff can be rapidly produced from thin sheet stock or molded polymer, using manufacturing processes such as die-cutting, laser cutting, injection molding, water-jet cutting, or die casting. This approach enables inexpensive design iterations and application-specific customization, such as varying the jet height, slot geometry, or spur placement, simply by exchanging the standoff. The jet plate may likewise be fabricated using laser drilling or chemical etching to create bespoke nozzle arrays tailored to the thermal requirements of the target device, all without altering the other module components. This modularity and manufacturing flexibility make the cooling module highly adaptable to a wide range of electronic cooling applications.

The cooling module is amenable to a variety of alternative embodiments and operational modes. For example, the module may be operated with a range of coolants, including dielectric fluids, water-glycol mixtures, or two-phase refrigerants. The dimensional parameters of the nozzles and exit slots can be adjusted to accommodate varying viscosity or vapor-quality levels, ensuring optimal performance across different fluid types. In applications requiring high heat dissipation over large areas, multiple cooling modules can be fluidly connected in parallel or series, with shared inlet and outlet manifolds, to service large substrates or multi-chip packages. The modular design also facilitates the integration of temperature or pressure sensors within the housing or base plate, enabling closed-loop control of coolant flow rate and real-time monitoring of thermal performance. Furthermore, the housing may be additively manufactured to incorporate complex spur geometries or structural mounting bosses without the need for secondary machining, further enhancing design flexibility and integration potential.

What is claimed is:

1. A cooling module for dissipating heat from a heat-generating electronic device, comprising:
(a) a base plate formed of a thermally conductive material and having a substantially planar impingement surface;
(b) a jet plate positioned above the base plate, the jet plate including an array of nozzles configured to generate high-velocity coolant jets directed toward the impingement surface;
(c) a standoff interposed between the jet plate and the base plate, the standoff having a thickness that defines a jet height and comprising strips of material that partition an impingement region into discrete flow chambers and exit slots that communicate with the discrete flow chambers;
(d) a housing enclosing the base plate, the standoff, and the jet plate, the housing defining an inlet plenum upstream of the jet plate, an exit channel downstream of the standoff, and connecting spurs fluidly coupling the exit slots to the exit channel; and
(e) inlet and outlet ports formed in the housing and adapted to couple the cooling module to an external fluid-delivery system; wherein the standoff is configured to route effluent coolant from each discrete flow chamber through its corresponding exit slots into the connecting spurs with reduced lateral travel, thereby mitigating wash-out of adjacent jets.

2. The cooling module of claim 1, wherein the impingement surface is free of machined flow-routing features.

3. The cooling module of claim 1, wherein the standoff is fabricated from sheet metal, plastic sheeting, thermoplastic, or thermoset resin.

4. The cooling module of claim 3, wherein the standoff is manufactured by die-cutting, laser cutting, water-jet cutting, injection molding, or die casting.

5. The cooling module of claim 1, wherein widths or pitches of the exit slots vary along the standoff to balance coolant flow across the impingement region.

6. The cooling module of claim 1, wherein the jet plate further comprises a fluid exit port hole distinct from the nozzles, the fluid exit port holes being configured to allow a portion of the coolant to exit the cooling module after that portion has impinged on the impingement surface of the base plate.

7. The cooling module of claim 1, wherein the standoff mechanically supports the jet plate under a compression load applied by a gasket disposed between the housing and the jet plate.

8. The cooling module of claim 1, wherein the connecting spurs are positioned proximate central portions of the impingement surface to further shorten effluent travel distance.

9. The cooling module of claim 1, wherein the inlet plenum is configured to distribute coolant uniformly across the jet plate.

10. The cooling module of claim 1, wherein the cooling module is configured for customization by replacing the standoff or the jet plate or both without altering the base plate or housing.

11. The cooling module of claim 1, wherein the standoff further comprises a plurality of effluent isolators, each effluent isolator being a thin cross bar or strip of material extending beneath the jet plate and configured to partition the impingement region into a plurality of discrete chambers, each chamber corresponding to a subset of the array of nozzles, such that the effluent isolators force effluent to exit through a nearest exit slot in the standoff.

12. The cooling module of claim 11, wherein the effluent isolators are arranged to create at least two or more discrete flow chambers beneath the jet plate, each flow chamber being fluidly isolated from adjacent flow chambers except at the exit slots.

13. The cooling module of claim 1, wherein the jet plate is fabricated from stainless steel, copper, or a high-performance polymer.

14. The cooling module of claim 1, wherein the base plate is formed from copper, copper alloy, or aluminum.

15. The cooling module of claim 1, wherein the housing further comprises a connection apron having a plurality of screw holes for securing the base plate to the housing.

16. The cooling module of claim 1, wherein the exit channel is defined by the housing and is configured to collect effluent from connecting spurs before discharge through the outlet port.

17. The cooling module of claim 1, wherein the module is adapted for use with a variety of coolants, including dielectric fluids, water-glycol mixtures, or two-phase refrigerants.

18. The cooling module of claim 1, wherein the standoff, jet plate, and housing are each dimensioned to substantially match a length and width of the base plate, providing a uniform assembly.

19. The cooling module of claim 1, wherein the standoff is replaceable to allow adjustment of jet height for different thermal loads.

20. A method of removing heat from a heat-generating electronic device, comprising:
(a) directing coolant through an inlet port into an inlet plenum of a cooling module;
(b) passing the coolant through nozzles in a jet plate to form high-velocity jets;
(c) impinging the high-velocity jets on a substantially planar impingement surface of a base plate to absorb heat;
(d) partitioning effluent coolant among discrete flow chambers defined by strips of a standoff disposed between the jet plate and the base plate;
(e) immediately routing the effluent coolant from each flow chamber through exit slots in the standoff into connecting spurs of a housing;
(f) combining the effluent coolant from the connecting spurs in an exit channel; and
(g) discharging the effluent coolant through an outlet port to an external reservoir or heat exchanger.

21. The method of claim 20, further comprising the step of adjusting the thickness of the standoff to vary a height between the jet plate and the base plate, thereby tuning cooling performance for different thermal loads.

22. The method of claim 20, wherein the step of partitioning effluent coolant among discrete flow chambers comprises arranging effluent isolators in a pattern selected from the group consisting of a grid, concentric circles, radial spokes, or a honeycomb, to optimize flow distribution for a specific electronic device geometry.

23. The method of claim 20, further comprising the step of replacing the standoff or jet plate or both to customize the cooling module for a different electronic device or application without modifying the base plate or housing.

24. The method of claim 20, further comprising the step of monitoring temperature or pressure within the cooling module and adjusting coolant flow rate in response to the monitored values to maintain desired thermal performance.

25. The method of claim 20, wherein the coolant is selected from the group consisting of dielectric fluids, water-glycol mixtures, or two-phase refrigerants, and further comprising the step of selecting nozzle and exit slot dimensions to accommodate viscosity or phase characteristics of the chosen coolant.
